(19) United States
(12) Patent Application Publication
(10) Pub. No.: US 2005/0202582 A1
(43) Pub. Date: Sep. 15, 2005

(54) Sensor arrangement with improved spatial and temporal resolution

(75) Inventors: Bjorn-Oliver Eversmann, Munich (DE); Martin Jenkner, Planegg (DE); Christian Paulus, Weilheim (DE); Guido Stromberg, Munich (DE); Thomas Sturm, Kirchheim (DE); Annelie Stohr, Munich (DE)

Correspondence Address: DARBY & DARBY P.C., P. O. BOX 5257, NEW YORK, NY, 10150-5257, US

(73) Assignee: Infineon Technologies AG, Munich (DE)

(21) Appl. No.: 11/035,765

(22) Filed: Jan. 13, 2005

Related U.S. Application Data
(63) Continuation of application No. PCT/DE03/02470, filed on Jul. 22, 2003.

(30) Foreign Application Priority Data
Jul. 31, 2002 (DE) 102 34 942.8

(51) Int. Cl. H01L 21/00; G01N 27/26

(52) U.S. Cl. 438/48; 204/416

(57) ABSTRACT

Sensor arrangement having sensor arrays arranged in crossover regions of row and column lines, each of the sensor arrays having a coupler and a sensor element, which influences current flow between a row and column line through the coupler, an accumulative current flow detector that detects accumulative current flow from individual electric current flows provided by the sensor arrays, and a decoder that determines a sensor element at which a sensor signal is present from the accumulative electric current flows. Accumulative current flows which satisfy a predetermined first criterion can be determined from the detected accumulative current flows, and from the accumulative current flows determined an accumulative current flow can be selected as an accumulative current flow which represents a sensor signal and which satisfies a predetermined second criterion, and the sensor element at which a sensor signal is present can be determined from the selected accumulative current flow.

### CROSS-REFERENCE TO RELATED APPLICATION

This application is a continuation of International Patent Application Serial No. PCT/DE2003/002470, filed Jul. 22, 2003, which published in German on Feb. 26, 2004 as WO 2004/017423, and is incorporated herein by reference in its entirety.

### FIELD OF THE INVENTION

The invention relates to a sensor arrangement.

### BACKGROUND OF THE INVENTION

Present-day developments in many fields of science and technology are characterized by the fact that areas formerly independent of one another are increasingly being combined. One example of an interdisciplinary area is the interface between biology and semiconductor technology. A topic of present-day research is, by way of example, the economically very interesting coupling between biological cell assemblages (such as neurons, for example) and silicon microelectronics.

In accordance with one concept, a biological system is grown on the surface of a semiconductor-technological sensor and is examined in spatially or temporally resolved fashion by means of sensor electrodes arranged in matrix form on the surface of the sensor. In accordance with this concept, the metabolism parameters of the cells can be recorded for example by detecting local pH values with the aid of ion-sensitive field-effect transistors (ISFETs). In terms of its basic principle, an ISFET is constructed similarly to a metal-insulator-semiconductor field-effect transistor (MISFET). It differs from a conventional MISFET, in particular also from a conventional MOSFET, in that the conductivity of the channel region is not controlled by means of a metal electrode, but rather by means of an arrangement having an ion-sensitive layer, an electrolyte and a reference electrode. In other words, electrically charged biological molecules control the conductivity of the ISFET, which is detected as a sensor variable.

Examining the reaction of a biological system to an electrical stimulation is of particular interest. Neurons (nerve cells) can generate a small ion current via ion channels in the cell membranes in specific regions of their surface, said current being detected by a sensor situated underneath. Such pulses typically last a few milliseconds, and the electrical voltage that forms in the gap between the nerve cell and the sensor electrode is often less than 1 mV. In order to achieve a sufficient spatial resolution, the distance between neighboring sensor electrodes in the horizontal and vertical direction on a sensor surface that is often arranged in matrix form should preferably be less than 20 μm, so that the surface of a sensor and the cross-sectional area of a cell are approximately of the same order of magnitude. These requirements can be achieved by means of silicon microtechnology.

In the case of sensor arrangements having a sufficiently small number of sensor arrays, in accordance with the prior art, the output signal of each sensor array is passed out of the matrix by means of a dedicated line and processed further. In the case of a larger number of sensor arrays or decreasing distances between neighboring sensor arrays, this principle encounters its limits owing to the high space requirement of the high number of lines.

Referring to FIGS. 1A and 1B, a description is given below of a concept which is known from the prior art and makes it possible to read larger or increasingly dense arrangements of sensor electrodes. FIG. 1A shows a sensor arrangement 100 having a multiplicity of sensor electrodes 101 arranged in matrix form. The sensor electrodes 101 are (at least partly) coupled to one another by means of row lines 102 and column lines 103. An electrical amplifier device 104 is in each case arranged in edge regions of the row lines 102. As is furthermore shown in FIG. 1A, the matrix-type sensor arrangement 100 is divided into a first matrix region 105 and a second matrix region 106, which can be operated independently of one another. In a manner similar to that during the operation of a memory arrangement, the output signal of a specific sensor electrode 101 is switched onto a common output line of a row or column via switch elements 111 (cf. FIG. 1B) within the sensor arrangement 100.

In accordance with the concept shown in FIG. 1A, FIG. 1B, the quantity of data that is to be read out and to be processed constitutes the limits of the performance of the system. If a sensor arrangement is intended to be operated with a sufficiently high spatial resolution (i.e. sufficiently many sensor electrodes arranged sufficiently densely) and with a sufficiently high temporal resolution (i.e. a sufficiently high read-out frequency) and also with a sufficiently high accuracy, then the quantity of data to be read out per time rises to values which can make requirements of the technologically available equipment that cannot be achieved at the present time. The signals on the row lines 102 and the column lines 103 cannot be passed out of the sensor arrangement 100 in parallel owing to the still very large number of lines. The requirements made of the high quantity of data of the n·m sensor electrodes to be read in the case of a matrix having m rows and n columns can exceed the performance of known technologies.

FIG. 1B illustrates a sensor electrode 101 in detail. The sensor electrode 101 is coupled to one of the row lines 102 and to one of the column lines 103. If a switch element 111 is closed, then the assigned sensor electrode 101 is selected and can be read. The sensor event detected by the sensor area 112 in the form of an electrical signal is amplified by means of an amplifier element 110 before it is communicated via the row line 102 to the edge of the sensor arrangement 100 illustrated in FIG. 1A.

To summarize, sensor arrangements for the spatially resolved and temporally resolved detection of analog electrical signals which are known from the prior art have the disadvantage, in particular, that the n·m sensor electrodes have to be read individually and the signals have to be forwarded to a signal-processing circuit portion. As a result, in the case of a high number n·m of sensor electrodes (m rows, n columns), large quantities of data that are to be processed rapidly occur, and have to be passed out of the matrix in amplified fashion with sufficient accuracy. This exceeds the performance limit of known concepts given the requirements made of the spatial and temporal resolution of such a system.

WO 00/62048 A2 discloses a sensor arrangement with electrically drivable arrays. WO 00/62048 A2 discloses an electrical sensor arrangement with a plurality of sensor positions, comprising at least two microelectrodes. Molecular substances can be detected electrochemically and charged molecules can be transported by means of the arrangement.

### SUMMARY OF THE INVENTION

The invention is based on the problem of providing a sensor arrangement with an improved spatial and temporal resolution. In this case, the intention, in particular, is to determine so-called sensor events in which, in spatially bound fashion and in restricted time intervals, the current flow on a sensor element exceeds amplitude or energy threshold values or has a characteristic form.

The sensor arrangement according to the invention has a plurality of row lines arranged in a first direction, a plurality of column lines arranged in at least a second direction, and a plurality of sensor arrays arranged in crossover regions of row lines and column lines. Each sensor array has at least one coupling device for electrically coupling a respective row line to a respective column line, and a sensor element assigned to the at least one coupling device, the sensor element being set up in such a way that the sensor element influences electric current flow through the at least one assigned coupling device. Furthermore, the sensor arrangement of the invention has an accumulative current flow detector which is electrically coupled to a respective end section of at least a portion of the row lines and of at least a portion of the column lines and serves for detecting a respective accumulative current flow from the individual electric current flows provided by the sensor arrays of the respective lines. Furthermore, the sensor arrangement has a decoding device, which is coupled to the row lines and the column lines and is set up in such a way that those sensor elements at which a sensor signal is present can be determined from at least a portion of the accumulative electric current flows which can be fed to the decoding device via the row lines and the column lines. The decoding device is set up in such a way that a plurality of accumulative current flows which satisfy a predetermined first selection criterion can be determined from the detected accumulative current flows, that from the accumulative current flows determined at least one accumulative current flow can be selected as an accumulative current flow which represents a sensor signal and which satisfies a predetermined second selection criterion, and that the sensor element at which the sensor signal is present can be determined from the selected accumulative current flow.

Clearly, according to the invention, from the detected accumulative current flows, those which satisfy a first selection criterion are determined in a two-stage method.

One of the following selection criteria may be used as the first selection criterion:
the amplitude of the accumulative current flow is greater than a first amplitude threshold value for a predetermined time duration,
the energy of the accumulative current flow is greater than an energy threshold value for a predetermined time duration,
the correlation of an accumulative current flow with respect to one or a plurality of other accumulative current flows is greater than a correlation threshold value for a predetermined time duration.

To put it another way, this means that, in a first stage of the method, a superset (set of the accumulative current flows determined) of accumulative current flows is formed, which forms the initial basis for the second stage of the method. Clearly, a preselection of accumulative current flows thus takes place in the first stage, the superset containing the accumulative current flows, which represents a sensor event with a probability corresponding to the respective first selection criterion.

In the second method stage, a check is made for one or a plurality of accumulative current flows of the superset to ascertain whether the accumulative current flow or flows of the superset satisfy a second selection criterion. The second selection criterion is a second amplitude threshold value, by way of example. To put it another way, a check is made in the second method step to ascertain whether the amplitude of the respective accumulative current flow is greater than the second amplitude threshold value for a predetermined time duration. If the second selection criterion is satisfied, then the accumulative current flow/accumulative current flows is/are selected. The sensor element/sensor elements at which a sensor signal is present is/are determined from the selected accumulative current flow/accumulative current flows.

In accordance with one refinement of the invention the decoding device is set up in such a way that the accumulative current flows determined are checked with regard to the second selection criterion in an order according to falling probability that the respective accumulative current flow represents a sensor signal.

To put it another way, the accumulative current flows determined are prioritized with regard to the processing order, i.e. with regard to the order in which they are checked with respect to the second selection criterion. The accumulative current flows determined are clearly sorted and processed in an order such that firstly the accumulative current flow with maximum probability that it represents a sensor signal is checked and the accumulative current flows with respectively lower probability are progressively checked.

This enables the sensor signals to be determined more rapidly and thus more cost-effectively.

In accordance with another refinement of the invention, the decoding device is set up in such a way that a sensor signal profile is determined with respect to the selected accumulative current flow. This procedure corresponds to estimating the sensor signal profile from the selected accumulative current flow.

The sensor signal profile determined may be subtracted from the signal profiles of the accumulative current flows determined, whereby updated accumulative current flows are formed. The selection of an accumulative current flow is then effected using the updated accumulative current flows. This makes it possible for information that has already been determined to be incorporated as prior knowledge in a subsequent iteration, so that the selection of the next accumulative current flow yields a more accurate and thus more reliable result.

It should be emphasized that the nomenclature “row line” and “column line” does not imply an orthogonal matrix. The row lines running in a first direction and the column lines running in at least one second direction may form any desired angle with one another. According to the invention, it is possible for as many different lines as desired to be laid at any desired angles over the sensor arrangement and for coupling devices to be interconnected in crossover regions, which coupling devices “branch off” a specific electric current from one line into the other line. One of the at least one second direction may, but need not, run orthogonally with respect to the first direction. The row lines arranged along the first direction are provided, in particular, preferably for current feeding (but also for current discharging), and the column lines arranged along the at least one second direction are provided, in particular, for current discharging.

Whereas in known realizations of sensor arrangements, all the sensor arrays are read successively and, therefore, nm signals are determined in one cycle, only n+m signals are output and digitized in the realization according to the invention. Consequently, it is possible to achieve significantly increased sampling rates, i.e. a significantly improved temporal resolution of the sensor arrangement.

A further advantage is that a genuine snapshot of the potential conditions on the active sensor surface is possible. Whereas in the conventional case the matrix elements are read successively and are thus detected in a manner temporally staggered with respect to one another, the instantaneous situation can be “retained” and subsequently evaluated in the case of the invention. This results inter alia from the small number of electrical signals to be read out, which can be read out virtually instantaneously.

The invention is furthermore distinguished by the fact that it is based on very weak model assumptions and that, in particular, special prior knowledge about the signal profile or the signal scaling of a sensor signal is not necessary.

Moreover, the required computational complexity is relatively low.

Furthermore, the invention is also suitable for use in a sensor arrangement in which a plurality of the sensors are active simultaneously, and also given the existence of relatively strong noise influences.

Furthermore the sensor arrangement according to the invention has the advantage that switching functions for the selection of a sensor array are unnecessary within the sensor arrangement. This is necessary in accordance with the prior art for the selection of a specific sensor array and results in a high susceptibility to interference on account of instances of capacitive coupling in from one switched line to other lines, for example measurement lines. The invention thereby increases the detection sensitivity. The invention likewise suppresses undesirable interactions between a sensor array and the examination object arranged thereon (for example a neuron) on account of instances of galvanic, inductive or capacitive coupling in.

The decoding device of the sensor arrangement according to the invention may be divided into a row decoding device, to which the accumulative electric current flows of the row lines can be fed, and a column decoding device, to which the accumulative electric current flows of the column lines can be fed. The row decoding device is set up in such a way that information about those sensor elements at which a sensor signal is possibly present can be determined from at least a portion of the accumulative electric current flows of the row lines independently of the accumulative current flows of the column lines. The column decoding device is set up in such a way that information about those sensor elements at which a sensor signal is possibly present can be determined from at least a portion of the accumulative electric current flows of the column lines independently of the accumulative current flows of the row lines. Furthermore, the decoding device is set up in such a way that those sensor elements at which a sensor signal is present can be determined by means of joint evaluation of the information determined by the row decoding device and the column decoding device.

By virtue of the fact that, illustratively, the accumulative current flows of the row lines and of the column lines are first of all decoded independently of one another, the decoding speed is increased and possible with a lower outlay on resources. It is also possible for even the accumulative current flows of different row lines (or different column lines) first of all to be evaluated independently of the accumulative current flows of other row lines (or other column lines) and for these separate results then to be adjusted.

In accordance with a further refinement of the sensor arrangement according to the invention, said sensor arrangement may have a voltage source, which is coupled to at least a portion of the row lines and of the column lines in such a way that a predetermined potential difference is provided for at least a portion of the coupling devices.

By way of example, a first reference potential (for example a supply voltage V_{dd}) may be applied to at least a portion of the column lines and at least a portion of the row lines are connected to a second reference potential (for example a lower reference potential Vₛₛ such as the ground potential). If the same electrical voltage is present at each of the coupling devices in crossover regions between the row and column lines to which the reference potentials described are applied, then the same quiescent current flows through each coupling device. A sensor event modulates the voltage at the coupling element and thus the current flow, which therefore represents a direct measure of the sensor events at the sensor element coupled to the respective coupling device.

Preferably, at least one coupling device is a current source controlled by the associated sensor element or a resistor controlled by the associated sensor element.

In other words, the electric current flow through a coupling device, in the case where the coupling device is configured as a current source controlled by the associated sensor element, depends on the presence or absence of a sensor event at the sensor element. The electrical resistance of the coupling device may also depend in a characteristic manner on whether or not a sensor event takes place at the assigned sensor element. In the case of such a variable resistance, the current flow through the coupling device for a fixed voltage between the assigned row and column lines is a direct measure of the sensor events effected at the sensor element. Designing the coupling device as a current source controlled by the associated sensor element or a resistor controlled by the associated sensor element enables the coupling devices to be realized in a manner exhibiting little complexity.

Preferably, at least one coupling device has a detection transistor having a first source/drain terminal coupled to one of the row lines, having a second source/drain terminal coupled to one of the column lines, and having a gate terminal coupled to the sensor element assigned to the coupling device.

Illustratively, the conductivity of the gate region of the detection transistor, preferably a MOS transistor, is influenced by whether or not a sensor event takes place at the assigned sensor element. If this is the case, i.e. if, by way of example, electrically charged particles (for example sodium and potassium ions) are brought into direct proximity to the sensor element from a neuron on the sensor element via ion channels, then these electrically charged particles indirectly alter the quantity of charge on the gate terminal of the detection transistor, thereby characteristically influencing the electrical conductivity of the channel region between the two source/drain terminals of the detection transistor. As a result, the current flow through the coupling device is influenced characteristically, so that the respective coupling device makes an altered contribution to the accumulative current flow of the respective row or column line. The configuration of the coupling device as a detection transistor constitutes a space-saving realization which exhibits little complexity and enables a cost-effective production and a high integration density of sensor arrays.

The simple circuitry realization of the sensor arrays of the sensor arrangement according to the invention means that the cells can be made very small, which permits a high spatial resolution of the sensor.

Furthermore, at least one coupling device of the sensor arrangement according to the invention may have a calibration device for calibrating the coupling device.

The semiconductor-technological components of a sensor array are generally integrated components, such as MOS transistors, for example. Since these integrated components within a sensor array are usually made very small in order to achieve a high spatial resolution, a statistical variation of their electrical parameters (for example threshold voltages in the case of a MOSFET) occurs on account of fluctuations in the process implementation during the production method.

The deviation of the threshold voltages and other parameters may be compensated for for example by performing a calibration for example with the aid of a data table. For this purpose, an electronic reference signal is in each case applied to individual sensor arrays of the matrix-type sensor arrangement, and the measured current intensities of the corresponding sensor elements are stored for instance in a table. During measurement operation, this table, which may be integrated as a database in the decoding device, serves for converting possibly erroneous measured values. This corresponds to a calibration.

As an alternative, the calibration device of the sensor arrangement according to the invention has a calibration transistor having a first source/drain terminal coupled to the row line, having a second source/drain terminal coupled to the gate terminal of the detection transistor and also to a capacitor coupled to the assigned sensor element, and having a gate terminal coupled to a further column line, it being possible for an electrical calibration voltage to be applied to the gate terminal of the calibration transistor by means of the further column line.

In accordance with the circuitry interconnection described, which requires a further transistor, namely the calibration transistor, and a capacitor compared with the above-described simple configuration of the coupling device as a detection transistor, the deviation of a parameter, such as, for example, the threshold voltage of the detection transistor, can be compensated for by a procedure in which an electrical potential is applied to the further column line, the calibration transistor consequently turns on and a node between the capacitor and the gate terminal of the detection transistor is charged to an electrical calibration potential. This calibration potential results from an electric current which is impressed in the row line and flows away into the column line through the detection transistor, acting as a diode. If the calibration transistor is turned off again because the voltage applied to the further column line is switched off, an electrical potential remains on the gate terminal of the detection transistor, which electrical potential permits a correction of the threshold voltage of the respective detection transistor for each sensor array of the sensor arrangement. Therefore, the robustness of the sensor arrangement according to the invention with respect to errors is improved with the use of a calibration device having a calibration transistor and a capacitor. In particular, impressing a zero current also enables any desired coupling device to be deactivated. If the calibration transistor is in the on state and if no current (zero current) is impressed in the row line, then the potential at the gate terminal of the detection transistor is reduced to an extent such that the detection transistor is turned off and remains correspondingly deactivated after the calibration transistor is switched off. This means that the associated sensor array, independently of the signal of the connected sensor element, contributes no signal to the accumulative signal of the row and column lines. In particular, this sensor array also does not contribute to the noise signal on the affected row and column lines, for which reason the later analysis of the signals at the remaining, still active sensor arrays is simplified.

Furthermore, at least one coupling device of the sensor arrangement according to the invention may have an amplifier element for amplifying the individual electric current flow of the coupling device. In particular, the amplifier element may have a bipolar transistor having a collector terminal coupled to the row line, an emitter terminal coupled to the column line, and a base terminal coupled to the second source/drain terminal of the detection transistor.

The use of a bipolar transistor as amplifier element, the design of which, with conventional semiconductor-technological methods, is not very complicated and is therefore possible in a cost-effective manner, provides a high-performance amplifier element having small dimensions on the sensor array, which can be used to achieve a high amplification of the often small current flows. This makes it possible to increase the sensitivity of the sensor arrangement.

Preferably, at least a portion of the row lines and of the column lines have an amplifier device for amplifying the accumulative electric current flow flowing in the respective row line and column line.

At least one sensor element of the sensor arrangement may be an ion-sensitive field-effect transistor (ISFET).

The functionality of an ISFET is described above. An ISFET constitutes a sensor element which can be produced with a low outlay in a standardized semiconductor-technological method and has a high detection sensitivity.

It is also possible for at least one sensor element on the sensor arrangement to be a sensor which is sensitive to electromagnetic radiation.

A sensor which is sensitive to electromagnetic radiation, for example a photodiode or another photosensitive element, enables the sensor arrangement to be operated as an optical sensor with a high repetition rate. The sensor arrangement according to the invention generally has the advantage that no further requirements are made of the sensor element except that a sensor event is intended to bring about an electrical signal.

The sensor arrays of the sensor arrangement are preferably formed essentially in rectangular fashion.

In this case, the sensor arrays are preferably arranged in matrix form. The column and row lines may be formed orthogonally with respect to one another along the edges of the rectangular sensor arrays. In other words, the row lines and the column lines of the sensor arrangement according to the invention may form essentially a right angle with one another.

In accordance with an alternative refinement of the sensor arrangement according to the invention, the sensor arrays are formed essentially in honeycomb-shaped fashion. In this case, honeycomb-shaped denotes a configuration of the sensor arrays in which the sensor arrays are hexagonal with pairs of parallel sides, furthermore preferably with 120° angles at each corner of the hexagon.

In the case of a honeycomb-shaped configuration of the sensor arrays, the row lines may form an angle of 60° with the column lines, and different column lines may either be parallel to one another or form an angle of 60° with one another.

The use of honeycomb-shaped sensor arrays achieves a particularly high integration density of sensor arrays, thereby achieving a high spatial resolution of the sensor arrangement.

Preferably, the sensor arrangement is divided into at least two regions that can be operated independently of one another, the sensor arrangement being set up in such a way that it is possible to predetermine which of the at least two regions are operated in a specific operating state. In this case, the regions may be arranged such that they are spatially directly neighboring (e.g. halves, quadrants) or be interleaved in one another, for example in such a way that, in the case of an orthogonal arrangement of sensor arrays, the coupling devices are connected for example in chessboard-like fashion to one or the other system of column and row lines.

The matrix-type sensor arrangement can thus be divided into different segments (for example into four quadrants) in order to increase the measurement accuracy on account of reduced line capacitances. By way of example, if it is known that sensor events cannot occur in a region of the sensor arrangement (for example because no neurons have grown in this region) then it is necessary only to examine the remaining region of the sensor arrangement, on which sensor events can take place. The supply of the unused region with supply voltages is therefore obviated. Furthermore, signals are to be evaluated only from that region in which sensor signals can occur. Moreover, for specific applications it may suffice to use only a partial region of the surface of the sensor arrangement which is smaller than the total surface of the sensor arrangement. In this case, the desired partial region can be connected in, which enables a particularly fast and not very complicated determination of the sensor events of the sensor arrays arranged on the partial region.

### BRIEF DESCRIPTION OF THE DRAWINGS

Exemplary embodiments of the invention are illustrated in the figures and are explained in more detail below.

FIG. 1A shows a sensor arrangement in accordance with the prior art;

FIG. 1B shows a sensor electrode of the sensor arrangement in accordance with the prior art as shown in FIG. 1A;

FIG. 2 shows a sensor arrangement in accordance with a first exemplary embodiment of the invention;

FIG. 3 shows a sensor arrangement in accordance with a second exemplary embodiment of the invention;

FIG. 4A shows a sensor array of a sensor arrangement in accordance with a first exemplary embodiment of the invention;

FIG. 4B shows a sensor array of a sensor arrangement in accordance with a second exemplary embodiment of the invention;

FIG. 5A shows a sensor array of a sensor arrangement in accordance with a third exemplary embodiment of the invention;

FIG. 5B shows a sensor array of a sensor arrangement in accordance with a fourth exemplary embodiment of the invention;

FIG. 5C shows a sensor array of a sensor arrangement in accordance with a fifth exemplary embodiment of the invention;

FIG. 5D shows a sensor array of a sensor arrangement in accordance with a sixth exemplary embodiment of the invention;

FIG. 6 shows a schematic view of a sensor arrangement according to the invention, which is partly covered with neurons, in accordance with the second exemplary embodiment of the sensor arrangement according to the invention as shown in FIG. 3;

FIG. 7 shows a sensor arrangement in accordance with a third exemplary embodiment of the invention; and

FIG. 8 shows a flow diagram illustrating the individual method steps for determining sensor signals.

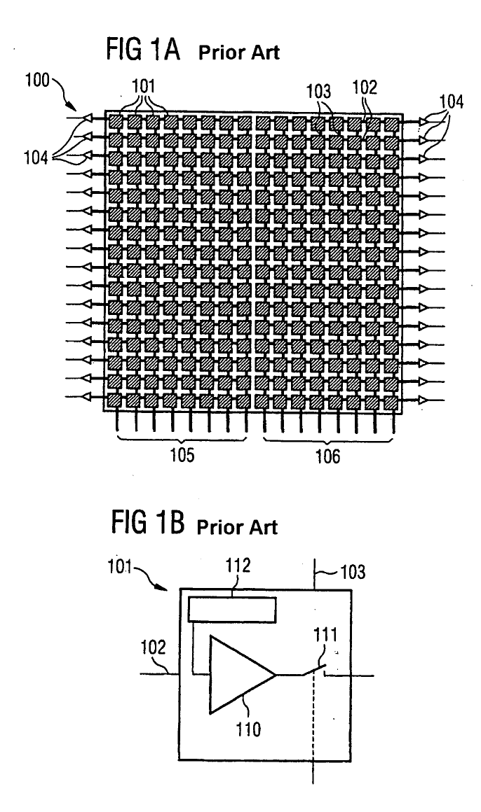

### DETAILED DESCRIPTION OF PREFERRED EMBODIMENTS OF THE INVENTION

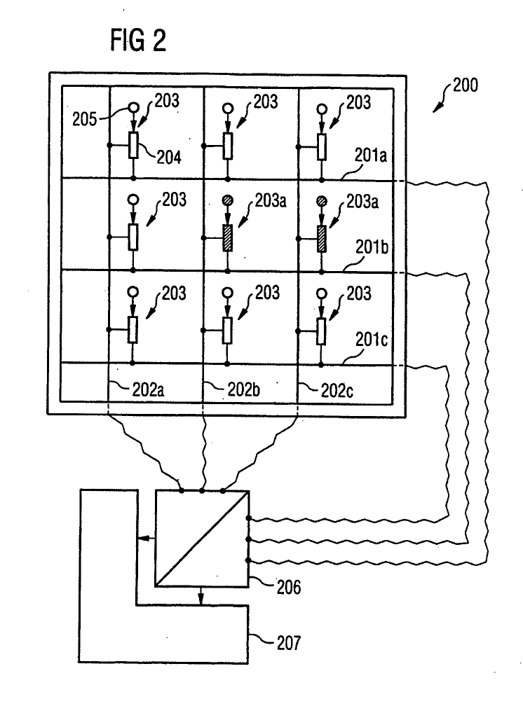

A description is given below, referring to FIG. 2, of a sensor arrangement in accordance with a first exemplary embodiment of the invention.

The sensor arrangement 200 shown in FIG. 2 has three row lines 201a, 201b, 201c arranged in a horizontal direction, three column lines 202a, 202b, 202c arranged in a vertical direction, and nine sensor arrays 203 arranged in the crossover regions between the three row lines 201a, 201b, 201c and column lines 202a, 202b, 202c, with a coupling device 204 for electrically coupling a respective row line 201a, 201b or 201c to a respective column line 202a, 202b or 202c and with a sensor element 205 assigned to the coupling device 204, the sensor element 205 being set up in such a way that the sensor element 205 influences the electric current flow through the assigned coupling device 204. Furthermore, the sensor arrangement 200 has a means 206 which is electrically coupled to a respective end section of the row lines 201a, 201b, 201c and of the column lines 202a, 202b, 202c and serves for detecting a respective accumulative current flow from the individual electric current flows provided by the sensor arrays 203 of the respective row and column lines. The sensor arrangement 200 furthermore has a decoding device 207, which is coupled to the row lines 201a, 201b, 201c and the column lines 202a, 202b, 202c and is set up in such a way that the activated sensor elements 203a at which a sensor signal is present can be determined from the accumulative electric current flows, which can be fed to the decoding device 207 via the row lines 201a, 201b, 201c and the column lines 202a, 202b, 202c.

The two activated sensor arrays 203a situated in the crossover regions between the second row 201b and the second and third columns 202b, 202c are emphasized visually in FIG. 2.

These sensor arrays 203a are those in which a sensor event takes place at the sensor element 205, on account of which the sensor element 205 characteristically influences the current flow through the coupling device 204. A voltage source (not shown in FIG. 2) provides a predetermined potential difference between each of the row lines 201a, 201b, 201c and each of the column lines 202a, 202b, 202c. Given this fixed potential difference, the current flow through the coupling devices 204 of the sensor arrays 203 is characteristically influenced by the sensor events at the assigned sensor elements 205. Illustratively, a greatly altered current flow can be detected particularly at the second row line 201b, since two of three sensor arrays 203 to which the row line 201b is coupled have an altered electric current flow on account of a sensor event. The second and third column lines 202b, 202c also have an (albeit less greatly) altered current flow since in each case one of three sensor arrays 203 coupled to said column lines 202b, 202c has an altered current flow. As shown schematically in FIG. 2, the accumulative current flows along the row lines 201a to 201c and the column lines 202a to 202c are provided to the means 206 for detecting accumulative current flows, which in turn provides the accumulative current flows detected to the decoding device 207. It can clearly be understood that, when examining the correlation of the accumulative currents of a respective row line with a respective column line, it is possible to determine which sensor arrays 203a are activated.

A description is given below, with reference to the flow diagram 800 in FIG. 8 of how it is determined whether and at which sensor element a sensor event has occurred. The decoding device 207 is set up in such a way that the method steps described are carried out by the decoding device 207.

FIG. 8 shows symbolically, in a first block 801, that the accumulative current flows are read in by the means 206 for detecting accumulative current flows.

Using the accumulative current flows read in, in a first method stage (block 802), a set of possible sensor events is formed; to put it another way accumulative current flows which satisfy a first selection criterion explained in greater detail below are determined.

For at least a portion of the accumulative current flows of the set of possible sensor events, those accumulative current flows which are assumed in each case to represent a sensor event and thus a sensor signal are finally selected in a second method stage (block 803).

The selected accumulative current flows and/or estimated sensor signal profiles determined from the accumulative current flows are stored in a list in an electronic file (block 804) and output to a user as required.

The following notation is used for the following explanation of the individual method steps.

It shall be the case that nεN is the number of columns, mεZ is the number of columns in the sensor arrangement. For 1≦i≦n and 1≦j≦m,
zᵢⱼ:N₀→ [symbol] (1)
shall define the signal values on the sensor cell (i, j),
   cᵢ:N₀→ [symbol] (2)
shall define the accumulative signal (accumulative current flows) of the i-th column and
   rⱼ:N₀→ [symbol] (3)
shall define the accumulative signals of the j-th row.

The analysis interval shall be given by {tₛₜₐᵣₜ, . . . ,t_{end}}⊂N₀. The method supplies, as the result, a set of detected sensor events.

D⊂{tₛₜₐᵣₜ, . . . ,t_{end}}× [symbol] ×{1, . . . ,n}×{1, . . . m}. (4)

A detected sensor event (corresponds to a selected accumulative current flow as the result of the second method stage, d=(tₐ, vₐ, i, j)εD is in this case given by its anchor instant tₐ, its anchor value vₐ and the sensor cell (i, j) on which the sensor event takes place.

An explanation is given below of a few alternative possibilities for determining a superset of sensor events (block 802) from the detected accumulative current flows provided.

Firstly, a threshold value analysis is carried out; to put it another way, as the first selection criterion a check is made to ascertain whether the amplitude of a respective accumulative current flow is greater than a predetermined amplitude threshold value for a predetermined time duration.

Consequently, two parameters are prescribed in the case of the threshold value analysis:
the amplitude threshold value vₘᵢₙε [symbol] ⁺ and
the minimum time duration tₘᵢₙεN.

A sensor event d=(tₐ, vₐ, i, j)εD is detected as possible on a sensor cell (i, j) if, in a time interval having a length greater than or equal to the minimum time duration tₘᵢₙ, the relevant column and row sums, i.e. the accumulative current flows in the relevant columns and rows, all exceed the amplitude threshold value vₘᵢₙ in terms of magnitude. In this case, the directions of exceeding must be identical for each fixed step, i.e. either row and column sums are both greater than or equal to the amplitude threshold value vₘᵢₙ or both are less than or equal to the negated amplitude threshold value −vₘᵢₙ.

The instant at which the minimum—in terms of magnitude—from corresponding row and column sums is the greatest is detected as the anchor instant tₐ and the corresponding, associated value is detected as the anchor value vₐ.

This corresponds to a procedure in accordance with the following specification:

$${v}^{i , j} : \{ {t}_{start} , … , {t}_{end} \} \to ℛ , \\ t ↦ \{ \begin{matrix}min ( {c}_{i} ( t ) , {r}_{j} ( t ) ) & if {c}_{i} ( t ) \geq 0 and {r}_{j} ( t ) \geq 0 , \\ max ( {c}_{i} ( t ) , {r}_{j} ( t ) ) & if {c}_{i} ( t ) < 0 and {r}_{j} ( t ) < 0 , ( \text{?} \\ 0 & otherwise . \end{matrix} \\ \text{?} \text{indicates text missing or illegible when filed} \qquad ( 5 )$$

If D⊂{tₛₜₐᵣₜ, . . . ,t_{end}}× [symbol] {1, . . . ,n}×{1, . . . m} is the result of the analysis, then the following holds true:
d=(tₐ, vₐ, i, j)εD (7)
precisely when t₀, t₁, ε{tₛₜₐᵣₜ, . . . ,t_{end}} where t₁−t₀≧tₘᵢₙ and tₐε{t₀, . . . ,t₁} where
(i) ∥v^{ij}(t₀−1)∥<vₘᵢₙ, (8)
(ii) ∥v^{ij}(t)∥≧vₘᵢₙ for all tε{t₀, . . . ,t₁} (9)
(iii) ∥v^{ij}(tᵢ+1)∥<v_{min′} (10)
(iv) vᵢⱼ(tₐ)=vₐ and (11)

$$( v ) ‖ {v}_{a} ‖ = {max}_{t ∈ \{ {t}_{0} , … , {t}_{1} \}} ( ‖ {v}^{ij} ( t ) ‖ ) . \qquad ( 12 )$$

In an alternative procedure, in which as the first selection criterion a check is made to ascertain whether the energy of the accumulative current flow is greater than an energy threshold value for a predetermined time duration, an energy analysis of the accumulative current flows is carried out.

The following three parameters are prescribed in the case of the energy analysis:
a minimum average power pₘᵢₙε [symbol] ⁺,
the duration of the observation interval ΔtεN and
a minimum distance between two sensor events t_{dist}εN.

A sensor event d=(tₐ, vₐ, i, j) is detected as possible on a sensor cell (i, j) if, over a time interval having the length Δt, the average power of the minimum—in terms of magnitude—from corresponding row and column sums does not fall below the minimum average power pₘᵢₙ. Anchor instant tₐ and anchor value vₐ are produced in the same way as in the case of the threshold value analysis. Two sensor events are considered to be identical if the anchor instants tₐ are at a distance from one another that is less than the minimum distance between two sensor events t_{dist}.

In the following description of the energy analysis, v and D are identical to the threshold value analysis.

The following procedure is effected for t₀=tₛₜₐᵣₜ to t_{end}:

Consider all
d=(tₐ, vₐ, i, j)ε{tₛₜₐᵣₜ, . . . ,t_{end}}× [symbol] ×{1, . . . ,n}×{1, . . . m}
where
(i) tₐε{t₀, . . . ,t₀+Δt−1}, (13)

$$\begin{matrix}( ii ) \frac{1}{Δ t} \cdot {\sum }_{t = {t}_{0}}^{{t}_{0} + Δ t - 1} {( {v}^{ij} ( t ) )}^{2} \geq {p}_{min} , & ( 14 ) \\ ( iii ) {v}^{ij} ( {t}_{a} ) = {v}_{a} and & ( 15 ) \\ ( iv ) ‖ {v}_{a} ‖ = {max}_{t ∈ \{ {t}_{0} , … , {t}_{0} + Δ t - 1 \}} ( ‖ {v}^{ij} ( t ) ‖ ) . & ( 16 )\end{matrix}$$

\tilde{d}=(\tilde{t}ₐ, \tilde{v}ₐ, i, j) shall be the sensor event detected last on the sensor cell (i, j).

If |tₐ−\tilde{t}ₐ|<t_{dist} holds true and
(a) \tilde{v}ₐ>vₐ: reject d,
(b) \tilde{v}ₐ≦vₐ: remove \tilde{d} from D and add d to D.

If |tₐ−\tilde{t}ₐ|≧t_{dist} holds true, then add d to D.

In another alternative procedure, in which as the first selection criterion a check is made to ascertain whether the correlation of an accumulative current flow with respect to one or a plurality of other accumulative current flows is greater than a correlation threshold value for a predetermined time duration, clearly a correlation analysis is carried out.

As an alternative, in the case of each of the different alternatives described above, provision may be made for filtering the accumulative current flows, i.e. the row and column sums, and for performing the respective analysis on the filtered row and column sums. Prior knowledge about noise influences and/or signal profiles of the individual sensor events is preferably introduced in the choice of filtering.

In this connection, it should be noted that, in the case of all the first selection criteria described, both the time duration and the respective threshold value depend on the actual application and are to be set in an application-specific manner.

The result of the first method stage is a set of accumulative current flows determined which possibly represent a sensor event and a sensor signal associated therewith. The set of accumulative current flows determined is buffer-stored in a memory (not illustrated).

Afterward, in the second method stage (block 803), those accumulative current flows which satisfy a second selection criterion are selected from the accumulative current flows determined.

In the context of the second method stage, a selection is effected with event prioritization of the accumulative current flows.

The following parameters are prescribed in this submethod:
a minimum anchor value v_{a,min},
an event precursor time (the time steps between event start and the anchor instant tₐ) tₚᵣₑ,
an event post-cursor time (the time steps between anchor instant tₐ and the event end) tₚₒₛₜ,
a maximum prioritization tₚᵣᵢₒ,
a maximum prioritized distance δₚᵣᵢₒ,

In the second method stage, the buffer-stored accumulative current flows are preferably ordered according to advancing (increasing) anchor instant tₐ and the accumulative current flows which satisfy the second similarity criterion explained in more detail below are selected and the other accumulative current flows are rejected.

The ordered list of the accumulative current flows that have been determined and buffer-stored is processed progressively accumulative current flow by accumulative current flow.

An accumulative current flow is selected and thus classified as representing a sensor event d=(tₐ, vₐ, i, j) if the anchor value vₐ is greater than or equal to the minimum anchor value v_{a,min}. If this is not the case, the accumulative current flow currently being processed and checked is rejected and erased from the list of possible sensor events.

If an accumulative current flow is selected as representing a sensor event d=(tₐ, vₐ, i, j) then an estimation of the sensor signal profile of the sensor event in the time interval {tₐ−tₚᵣₑ, . . . ,tₐ+tₚₒₛₜ} is calculated.

The calculated estimated sensor signal profile of the sensor event is subtracted from the accumulative current flows buffer-stored in the ordered list. The subtraction thus also brings about an alteration of the accumulative current flows and thus also of the respective anchor instants tₐ and anchor values vₐ, and also possibly a shift in the accumulative current flows in the list.

If there are temporal and spatial superpositions between the buffer-stored accumulative current flows and the selected accumulative current flow, then the respective accumulative current flows are correspondingly updated and, if appropriate, re-sorted in the list.

This updating is effected, in accordance with this exemplary embodiment after each selection of an accumulative current flow, i.e. after each iteration. As an alternative, however, the updating may also be effected only after a predetermined number of iterations.

If the updating is effected after each iteration, then there is no occurrence of superpositions with one or a plurality of already selected accumulative current flows during subsequent checks and a possible selection or a possible rejection of an accumulative current flow. In this way, shadow images can be eliminated if an accumulative current flow has been selected.

In order to take decisions in favor of the most probable accumulative current flows, that is to say in order to select the accumulative current flows which actually represent a sensor event with the highest probability, an alternative refinement of the invention may depart from the strict temporal arrangement of the accumulative current flows.

Accumulative current flows exhibiting a high degree of correspondence (that is to say in which the distance is less than δₚᵣᵢₒ) are prioritized in the list by at most tₚᵣᵢₒ time steps. In this way, accumulative current flows which represent a real sensor event with a relatively high probability can be checked and selected before accumulative current flows which represent a real sensor event with a relatively low probability are checked.

The distance δ is determined in accordance with the following procedure:
d=(tₐ, vₐ, i, j) shall be an accumulative current flow determined in the first method stage (and an accumulative current flow which, if appropriate, has already been updated in the second method stage). The distance δ between the row and column sums contributing to d is then given by:

$$δ := {\sum }_{t = {t}_{a} - {t}_{pre}}^{{t}_{a} + {t}_{post}} w ( t ) \cdot \vert {c}_{i} ( t ) - {r}_{j} ( t ) \vert \qquad ( 17 )$$
with the weighting function

$$\begin{matrix}w : \{ {t}_{a} - {t}_{pre} , … , {t}_{a } + {t}_{post} \} \to ℛ , & ( 18 ) \\ t ↦ \{ \begin{matrix}\frac{1}{3 \cdot ( {t}_{pre} + 1 + {t}_{post} )} {( \frac{t - {t}_{a} + {t}_{pre}}{{t}_{pre}} )}^{2} & if t \leq {t}_{a} \\ \frac{1}{3 \cdot ( {t}_{pre} + 1 + {t}_{post} )} {( \frac{{t}_{a} + {t}_{post} - t}{{t}_{post}} )}^{2} & if t > {t}_{a}\end{matrix} & ( 19 )\end{matrix}$$

The prioritization is effected in accordance with the following procedure:
d=(tₐ, vₐ, i, j) shall be an accumulative current flow determined in the first method stage (and an accumulative current flow which, if appropriate, has already been updated in the second method stage) and δ should be the distance between the row and column sums contributing to d. Its prioritization then results in accordance with the following specification:

$$p := \{ \begin{matrix}⌊ ( 1 - \frac{δ}{{δ}_{prio}} ) {t}_{prio} ⌋ & if δ \leq {δ}_{prio} , \\ 0 & otherwise .\end{matrix}$$

The sensor event signal profile is calculated in accordance with the following procedure:
v^{ij} shall be the signal value profile of the accumulative current flow considered (as described in [5] and [6]). d=(tₐ, vₐ, i, j) shall be an accumulative current flow that is determined in the first method stage and selected in the second method stage. The estimated signal profile u of d results in accordance with
   u: {tₐ−tₚᵣₑ, . . . ,tₐ+tₚₒₛₜ})→ [symbol] , (21)
   t|→w(t)·v^{ij}(t) (22)
with the weighting function

$$\begin{matrix}w : \{ {t}_{a} - {t}_{pre} , … , {t}_{a } + {t}_{post} \} \to ℛ , & ( 23 ) \\ t ↦ \{ \begin{matrix}\sqrt{\frac{t - {t}_{a} + {t}_{pre}}{{t}_{pre}}} & if t \leq {t}_{a} , \\ \sqrt{\frac{{t}_{a} + {t}_{post} - t}{{t}_{post}}} & if t > {t}_{a}\end{matrix} & ( 24 )\end{matrix}$$

The result of the second method stage is thus a list of selected accumulative current flows that are assigned to a respective sensor event, and additionally the indication of the respective sensor at which the sensor event was determined.

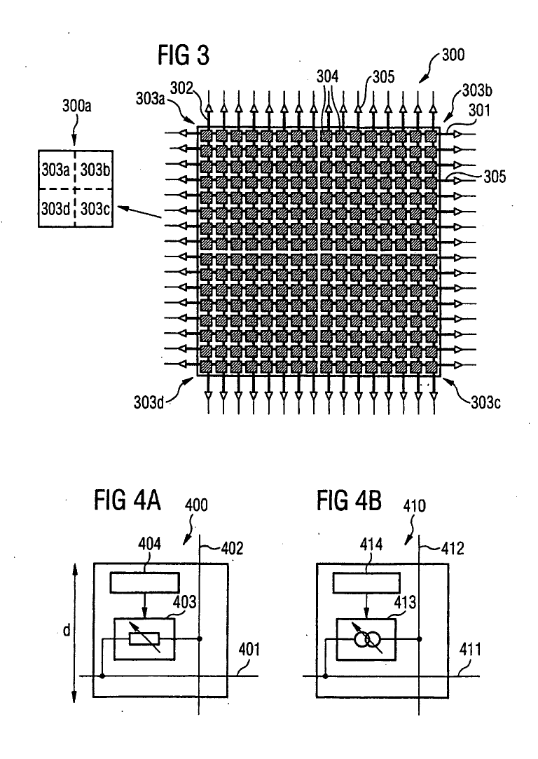

FIG. 3 shows a sensor arrangement in accordance with a second preferred exemplary embodiment of the invention.

The sensor arrangement 300 is constructed similarly to the sensor arrangement 200 described with reference to FIG. 2. In particular, the sensor arrangement 300 has sixteen row lines 301 and sixteen column lines 302. According to the invention, therefore, 32 accumulative current signals are to be detected, whereas 256 current signals of the 256 sensor arrays 304 would have to be detected in the case of a concept known from the prior art. In the case of the sensor arrangement 300 shown in FIG. 3, the sensor arrays 304 are formed in rectangular fashion. The row lines 301 and the column lines 302 form a right angle with one another. The sensor arrangement 300 is divided into four partial regions 303a, 303b, 303c, 303d that can be operated independently of one another, the sensor arrangement 300 being set up in such a way that it is possible to predetermine which of the four partial regions 303a to 303d are operated. The arrangement of the four partial regions 303a to 303d within the sensor arrangement 300 is shown in the schematic sketch 300a in FIG. 3. Each row line 301 and each column line 302 of the sensor arrangement 300 has an amplifier device 305 for amplifying the accumulative electric current flow flowing in the respective row line 301 and column line 302.

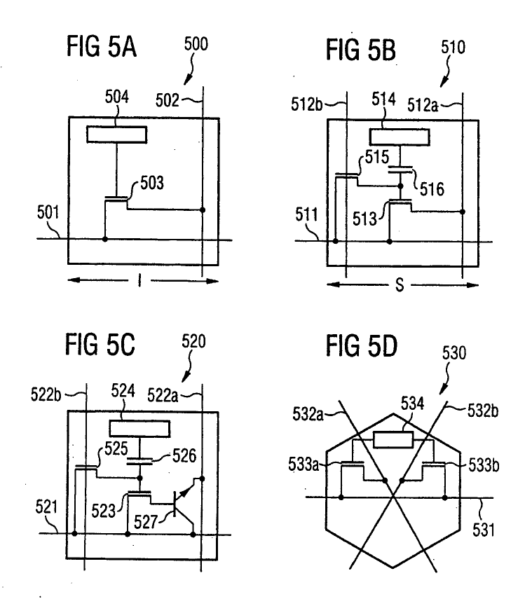

Possibilities for the detailed construction of the sensor arrays 304 are explained below on the basis of preferred exemplary embodiments with reference to FIG. 4A to FIG. 5D.

FIG. 4A shows a sensor array 400 in accordance with a first exemplary embodiment of the invention.

The sensor array 400 is arranged in a crossover region between a row line 401 and a column line 402. The row line 401 is coupled to the column line 402 via a coupling device 403 via two electrical crossover points. The coupling device 403 is designed as a resistor that can be controlled by a sensor element 404. In other words, a sensor event at the sensor element 404 has the effect of influencing the electrical resistance of the coupling device 403 in a characteristic manner. The sensor array 400 is a square having a side length d. In order to achieve an integration density of sensor arrays 400 in a sensor arrangement that is high enough for neurobiological purposes, the edge length d of the square sensor array 400 is preferably chosen to be less than 20 μm.

FIG. 4B shows a sensor array 410 in accordance with a second exemplary embodiment of the invention.

The sensor array 410 is arranged in a crossover region between a row line 411 and a column line 412. The sensor array 410 has a coupling device 413, by means of which the row line 411 is coupled to the column line 412 via two electrical coupling points. In accordance with the exemplary embodiment shown in FIG. 4B, the coupling device 413 is designed as a current source controlled by the sensor element 414. In other words, a sensor event at the sensor element 414 has the effect of influencing the electric current of the controlled current source 413 in a characteristic manner.

Thus, a controlled resistor or a controlled current source having a linear or nonlinear characteristic curve is provided as coupling device 403 or 413 within a sensor array 400 or 410, respectively. What is essential is that, with the aid of a suitable circuitry interconnection, a current flow is branched from a row line into a column line, which current flow is characteristically influenced by a sensor event.

FIG. 5A shows a sensor array 500 in accordance with a third exemplary embodiment of the invention.

The sensor array 500 shown in FIG. 5A is arranged in a crossover region between a row line 501 and a column line 502. By means of a coupling device designed as a detection transistor 503, the row line 501 is coupled to the column line 502 via two electrical crossover points. The detection transistor 503 has a first source/drain terminal coupled to the row line 501, a second source/drain terminal coupled to the column line 502, and a gate terminal coupled to the sensor element 504. The length l of a side of the sensor array 500 formed in square fashion is preferably less than 20 μm in order to achieve a sufficiently high spatial resolution.

A, preferably constant, electrical voltage is applied between the row line 501 and the column line 502. If a sensor event takes place at the sensor element 504, in the case of which electrically charged particles characteristically influence the potential of the gate terminal of the detection transistor 503, then the conductivity of the conductive channel between the two source/drain terminals of the detection transistor 503 is influenced on account of the sensor event. Therefore, the electric current flow between the first and second source/drain regions of the detection transistor 503 is a measure of the sensor event that has taken place at the sensor element 504. In other words, prior to a sensor event the sensor element 504 is brought to a predetermined electrical potential by means of a suitable measure, so that, between the two source/drain terminals of the detection transistor 503, a quiescent electric current flows from the column line 502 into the row line 501. If the electrical potential of the gate terminal is influenced, for example because a neuron coupled to the sensor element 504 emits an electrical pulse, the shunt current between the row line 501 and the column line 502 is thus altered on account of the altered electrical conductivity of the detection transistor 503.

Referring to FIG. 5B, a description is given below of a fourth exemplary embodiment of a sensor array of a sensor arrangement according to the invention.

The sensor array 510 shown in FIG. 5B is arranged in a crossover region between a row line 511 and a first column line 512a. As in the case of the sensor array 500, the sensor array 510 also has a detection transistor 513. Furthermore, the coupling device of the sensor array 510 has a calibration device for calibrating the coupling device. In accordance with the exemplary embodiment shown in FIG. 5B, the calibration device has a calibration transistor 515 having a first source/drain terminal coupled to the row line 511, having a second source/drain terminal coupled to the gate terminal of the detection transistor 513 and also to a capacitor 516 coupled to the assigned sensor element 514, and having a gate terminal coupled to a second column line 512b, it being possible for an electrical calibration voltage to be applied to the gate terminal of the calibration transistor 515 by means of the second column line 512b.

The calibration device of the sensor array 510 is set up in such a way that, by means of suitable control of the voltage signals on the first and second column lines 512a, 512b and also on the row line 511, it is possible to compensate for a deviation of parameters of the detection transistor 513 from parameters of detection transistors of other sensor arrays of the sensor arrangement according to the invention on account of nonuniformities during the production method. In particular, a statistical variation of the value of the threshold voltage of the detection transistors 513 of different sensor arrays of a sensor arrangement about a mean value may occur. The deviation of the threshold voltage between different sensor arrays can be compensated for by bringing the second column line 512b to an electrical potential such that the calibration transistor 515 is in the on state and the electrical node between the capacitor 516 and the gate terminal of the detection transistor 513 is brought to a calibration potential. The calibration potential is determined by the electric current which is fed into the row line 511 and flows through the detection transistor 513, connected as a diode. If the calibration transistor 515 is turned off again, an electrical voltage remains on the gate terminal of the detection transistor 513, which electrical voltage enables a correction of the different threshold voltages of different detection transistors 513 of different sensor arrays of a sensor arrangement.

It should be pointed out that the side length s of the square sensor array 510 is typically between approximately 1 μm and approximately 10 μm.

A description is given below, referring to FIG. 5C, of a fifth exemplary embodiment of a sensor array of the sensor arrangement according to the invention.

Like the sensor array 510, the sensor array 520 has the following components interconnected in a manner analogous to that shown in FIG. 5B: a row line 521, a first and a second column line 522a, 522b, a detection transistor 523, a sensor element 524, a calibration transistor 525 and a capacitor 526. Furthermore, the sensor array 520 has an amplifier element for amplifying the individual electric current flow of the coupling device of the sensor array 520. Said amplifier element is in the form of a bipolar transistor 527 having a collector terminal coupled to the row line 521, having an emitter terminal coupled to the first column line 522a, and having a base terminal coupled to the second source/drain region of the detection transistor 523. The electric current between the row line 521 and the first column line 522a is greatly amplified on account of the current-amplifying effect of the bipolar transistor 527. An increased sensitivity of the entire sensor arrangement is thereby achieved.

FIG. 5D shows a sensor array 530 in accordance with a sixth exemplary embodiment of the invention.

The sensor array 530 is formed in honeycomb-shaped fashion. A row line 531 in each case forms an angle of 600 with a first column line 532a and with a second column line 532b, the two column lines 532a and 532b also forming an angle of 600 with one another. The sensor array 530 has a first detection transistor 533a and a second detection transistor 533b. The gate terminals of the two detection transistors 533a, 533b are coupled to a sensor element 534. The first source/drain terminal of the first detection transistor 533a and the first source/drain terminal of the second detection transistor 533b are coupled to the row line 531. The second source/drain terminal of the first detection transistor 533a is coupled to the first column line 532a, whereas the second source/drain terminal of the second detection transistor 533b is coupled to the second column line 532b.

If a sensor event takes place at the sensor element 534, as a result of which electrical charge carriers are generated at the sensor element 534, then the conductivity of the channel regions of the first and second detection transistors 533a, 533b thereby changes in a characteristic manner. This results in a change on the one hand in the electric current flow from the row line 531 into the first column line 532a and on the other hand in the current flow from the row line 531 into the second column line 532b. In accordance with the concept shown in FIG. 5D, too, the accumulative current flows in the column lines and in the row lines are detected in edge regions of an arrangement of a multiplicity of sensor arrays 530 and the signals of the individual sensor arrays 530 are calculated by means of the temporal correlation of the accumulative current flows.

Since, on account of the space-saving configuration of the sensor arrays shown with reference to FIG. 4A to FIG. 5D, the sensor arrays can be made small enough to achieve a high spatial resolution, the noise level in the individual current of a sensor array may assume a value which may be of the same order of magnitude as the actual signal current. Although the noise current flows of all of the connected sensor elements accumulate on the row lines and the column lines, this uncorrelated signal is omitted during correlation calculation, so that only the sensor signal and the noise signal of a single sensor array contribute to the calculated measurement signal of said sensor array.

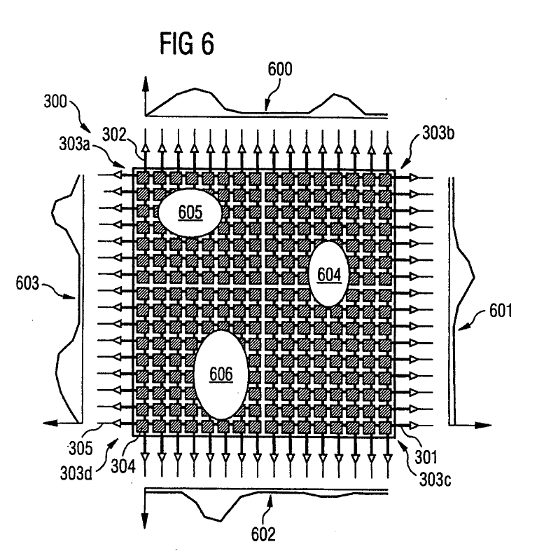

A description is given below, referring to FIG. 6, of the sensor arrangement 300 as shown in FIG. 3 in an active operating state.

In accordance with the operating state of the sensor arrangement 300 as shown in FIG. 6, a first neuron 604, a second neuron 605 and a third neuron 606 are arranged on the matrix-type arrangement of sensor arrays 304. In accordance with the preferred exemplary embodiment, the sensor arrays 304 are electrically conductive electrodes (e.g. Au, Pt, Pd) which are coated with a dielectric (e.g. SiO₂, Si₃N₄, Al₂O₃) and are electrically operatively connected to an amplifier (e.g. MOSFET). FIG. 6 furthermore shows a first projection 600, a second projection 601, a third projection 602 and a fourth projection 603 of the two-dimensional arrangement of neurons 604 to 606 on the matrix-type sensor arrangement 300. As described with reference to FIG. 3, the matrix-type sensor arrangement 300 is divided into four partial regions 303a to 303d each coupled to dedicated row and column lines, respectively. Therefore, the projections 600 to 603 in each case supply a two-dimensional mapping of the arrangement of neurons generating a sensor signal in the respective partial regions 303a to 303d. By way of example, the first neuron 604, which is essentially arranged in the second partial region 303b of the sensor arrangement 300, supplies a corresponding signal in the right-hand partial region of the first projection 600 in accordance with FIG. 6 and in the central region of the second projection 601. Since a small part of the first neuron 604 is also arranged in the third partial region 303c, a small signal of the first neuron 604 can be seen in the right-hand partial region of the third projection 602 in accordance with FIG. 6. In this way, each of the neurons 604 to 606 contributes to a signal in a respective part of the projections 600 to 603. The combined signals of the projections 600 to 603 supply information about the spatial arrangement of the neurons 604 to 606.

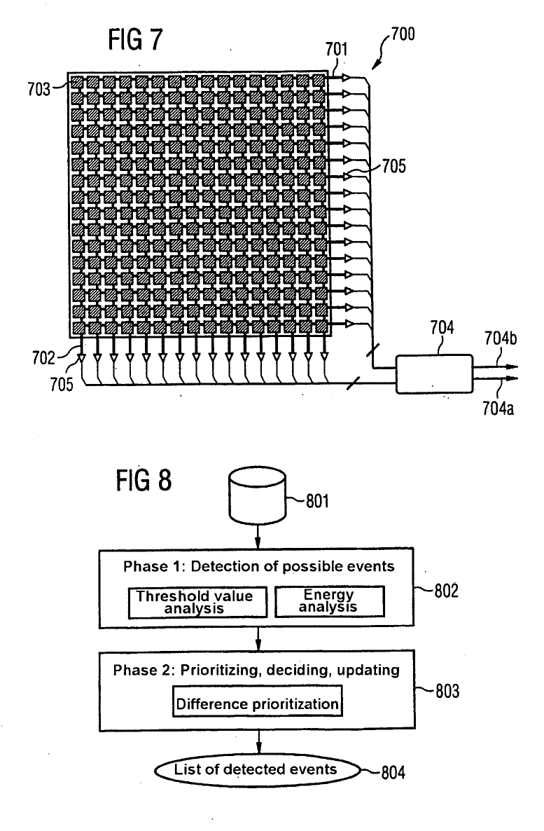

A description is given below, referring to FIG. 7, of a third preferred exemplary embodiment of the sensor arrangement according to the invention.

The sensor arrangement 700 shown in FIG. 7 has sixteen horizontally arranged row lines 701, sixteen vertically arranged column lines 702 and 256 sensor arrays 703 arranged in the crossover regions between the row lines 701 and the column lines 702. Each of the sensor arrays 703 is designed in the same way as the sensor array 500 shown in FIG. 5A. Electrically coupled means for detecting a respective accumulative current flow from the individual electric current flows provided by the sensor arrays 703 of the respective line 701, 702 are provided at the respective end sections of the row lines 701 and of the column lines 702. In accordance with the exemplary embodiment of the sensor arrangement 700 as shown in FIG. 7, said means are part of a decoding device 704 set up in the same manner as in the exemplary embodiment in FIG. 2. The decoding device 704 coupled to the row lines 701 and the column lines 702 is set up in such a way that it determines, from at least a portion of the accumulative electric current flows, which can be fed to the decoding device 704 via the row lines 701 and the column lines 702, those sensor elements of the sensor arrays 703 at which a sensor signal is present.

Furthermore, each row line 701 and each column line 702 has an amplifier device 705 for amplification and optionally a sample/hold device (not shown) for temporally accurate storage of the accumulative electric current flow flowing in the respective row line 701 and column line 702.

1. A sensor arrangement comprising:
a plurality of row lines arranged in a first direction;
a plurality of column lines arranged in at least a second direction;
a plurality of sensor arrays arranged in crossover regions of the row lines and the column lines, each of the sensor arrays comprising:
at least one coupling device for electrically coupling a respective row line to a respective column line; and
a sensor element assigned to the at least one coupling device, the sensor element being set up such that the sensor element influences electric current flow between a respective row line and a respective column line through the respective at least one coupling device;
an accumulative current flow detector, which is electrically coupled to a respective end section of at least a portion of the row lines and of at least a portion of the column lines and serves for detecting a respective accumulative current flow from the individual electric current flows provided by the sensor arrays of the respective lines; and
a decoding device, which is coupled to the row lines and the column lines and is set up such that at least one sensor element at which a sensor signal is present can be determined from at least a portion of the accumulative electric current flows which can be fed to the decoding device via the row lines and the column lines,
wherein the decoding device is set up such that a plurality of accumulative current flows which satisfy a predetermined first selection criterion can be determined from the detected accumulative current flows, that from the accumulative current flows determined at least one accumulative current flow can be selected as an accumulative current flow which represents a sensor signal and which satisfies a predetermined second selection criterion, and that the sensor element at which a sensor signal is present can be determined from the selected accumulative current flow.

2. The sensor arrangement as claimed in claim 1, wherein the decoding device is set up such that the first selection criterion is that the amplitude of the accumulative current flow is greater than a first amplitude threshold value for a predetermined time duration.

3. The sensor arrangement as claimed in claim 1, wherein the decoding device is set up such that the first selection criterion is that the energy of the accumulative current flow is greater than an energy threshold value for a predetermined time duration.

4. The sensor arrangement as claimed in claim 1, wherein the decoding device is set up such that the first selection criterion is that the correlation of an accumulative current flow with respect to at least one other accumulative current flow is greater than a correlation threshold value for a predetermined time duration.

5. The sensor arrangement as claimed in claim 1, wherein the decoding device is set up such that the accumulative current flows determined are checked with regard to the second selection criterion in an order according to falling probability that that accumulative current flow represents a sensor signal.

6. The sensor arrangement as claimed in claim 1, wherein the decoding device is set up such that a sensor signal profile is determined with respect to the selected accumulative current flow.

7. The sensor arrangement as claimed in claim 6, wherein the decoding device is set up such that the sensor signal profile determined is subtracted from the signal profiles of the accumulative current flows determined, whereby updated accumulative current flows are formed, and that the selection of an accumulative current flow is effected using the updated accumulative current flows.

8. The sensor arrangement as claimed in claim 1, further comprising a voltage source, which is coupled to at least a portion of the row lines and of the column lines such that a predetermined potential difference is provided for at least a portion of the coupling devices.

9. The sensor arrangement as claimed in claim 1, wherein the at least one coupling device is a current source controlled by the associated sensor element or a resistor controlled by the associated sensor element.

10. The sensor arrangement as claimed in claim 1, wherein the at least one coupling device has a detection transistor having a first source/drain terminal coupled to one of the row lines, a second source/drain terminal coupled to one of the column lines, and a gate terminal coupled to the sensor element assigned to the coupling device.

11. The sensor arrangement as claimed in claim 1, wherein the at least one coupling device has a calibration device for calibrating the coupling device.

12. The sensor arrangement as claimed in claim 1, which is set up such that the at least one coupling device has a deactivation function.

13. The sensor arrangement as claimed in claim 11, wherein the calibration device has a calibration transistor having a first source/drain terminal coupled to the row line, a second source/drain terminal coupled to the gate terminal of the detection transistor and also to a capacitor coupled to the assigned sensor element, and a gate terminal coupled to a further column line, it being possible for an electrical calibration voltage to be applied to the gate terminal of the calibration transistor by means of the further column line.

14. The sensor arrangement as claimed in claim 13, wherein the at least one coupling device has an amplifier element for amplifying the individual electric current flow of the coupling device.

15. The sensor arrangement as claimed in claim 14, wherein the amplifier element has a bipolar transistor having a collector terminal coupled to the row line, an emitter terminal coupled to the column line, and a base terminal coupled to the second source/drain terminal of the detection transistor.

16. The sensor arrangement as claimed in claim 1, wherein at least a portion of the row lines and of the column lines have an amplifier device for amplifying the accumulative electric current flow flowing in the respective row lines and column lines.

17. The sensor arrangement as claimed in claim 1, wherein at least a portion of the row lines and/or of the column lines have a sample/hold device for storing the accumulative electric current flow flowing in the respective row line and/or column line at a predetermined instant.

18. The sensor arrangement as claimed in claim 1, wherein at least one sensor element is an ion-sensitive field-effect transistor (ISFET).

19. The sensor arrangement as claimed in claim 1, wherein at least one sensor element has a MOSFET.

20. The sensor arrangement as claimed in claim 1, wherein at least one sensor element is sensitive to electromagnetic radiation.

21. The sensor arrangement as claimed in claim 1, wherein the sensor arrays are formed essentially in rectangular fashion.

22. The sensor arrangement as claimed in claim 21, wherein the row lines form essentially a right angle with the column lines.

23. The sensor arrangement as claimed in claim 1, wherein the sensor arrays are formed essentially in honeycomb-shaped fashion.

24. The sensor arrangement as claimed in claim 23, wherein the row lines form an angle of 60° with the column lines, and wherein different column lines are either parallel to one another or form an angle of 60° with one another.

25. The sensor arrangement as claimed in claim 1, which is divided into at least two regions that can be operated independently of one another, the sensor arrangement being set up such that it is possible to predetermine which of the at least two regions are operated.
